(19) United States
(12) Patent Application Publication
(10) Pub. No.: US 2019/0212282 A1
(43) Pub. Date: Jul. 11, 2019

(54) AUTOMATED MEASUREMENTS ON DRILL CUTTINGS WHILE DRILLING

(71) Applicant: Arcady Reiderman, Richmond, TX (US)

(72) Inventor: Arcady Reiderman, Richmond, TX (US)

(21) Appl. No.: 16/245,225

(22) Filed: Jan. 10, 2019

Related U.S. Application Data
(60) Provisional application No. 62/615,949, filed on Jan. 10, 2018.

(51) Int. Cl. G01N 24/08; E21B 21/01; E21B 49/00; E21B 49/08; G01R 33/44; G01V 3/32; G01V 3/38; G01V 5/12; G06K 9/62; G05B 13/04

(52) U.S. Cl. CPC G01N 24/081; E21B 21/01; E21B 49/003; E21B 49/08; G01R 33/448; E21B 7/00; G01V 3/38; G01V 5/12; G06K 9/6201; G05B 13/042; G01V 3/32

(57) ABSTRACT

An apparatus (and method) for automated measurements on drill cuttings comprising a sample catcher to collect a portion of the drill cuttings directly from a shaker, an at least one pneumatic actuator to move the collected portion from the sample catcher into a measurement sensitivity area created by a measurement module. The measurement module has a hermetically sealed enclosure and placed near the sample catcher. The sensitivity area is formed outside the enclosure and surrounded by the measurement module. The measurement module and the pneumatic actuator are controlled by an external unit placed away from the shaker. The measurement module can be a nuclear magnetic resonance (NMR) measurement module or other measurement module that performs high-throughput bulk sensitive measurements.

### BACKGROUND OF THE INVENTION

### Field of the Invention

This invention is related to evaluation of petrophysical properties of the earth formations while drilling an oil well. More specifically, the invention teaches methods and apparatus for evaluating petrophysical properties of the earth formations using measurements on drill cuttings. The measurements may include nuclear magnetic resonance (NMR) relaxometry.

### Background Art

Formations evaluation including NMR measurements can be done while drilling using well logging instruments placed on a drill collar. This type of measurements is typically high cost and functionally limited.

Advanced mud logging including measurements on drill cuttings is another known approach to formations evaluation while drilling (US20060272812). These measurements are typically done in laboratory, their throughput and functionality are not adequate to support the drilling process.

US20170161885 teaches measurements on drill cuttings while the drilling mud containing the cuttings is passed through the equipment called a “shale shaker”. Wellbore conditions are identified based on optical imaging technique allowing for determining the size, shape and texture of the cuttings. The technique does not address the earth formations evaluation.

Another prior art (US20160230482) teaches technique to determine fluid rheology via NMR/MRI (magnetic resonance imaging). The NMR/MRI based means and methods are disclosed for real-time in-vivo rheology measurements of drilling muds, especially for optimizing the recycling conditions and treatment of the mud, including continuous, one-step on-line measurement of mud-related parameters. The teaching does not address the earth formations characterization while drilling.

Cost efficient drilling would greatly benefit from lower cost and high throughput measurements to evaluate the rock formations being drilled through. It is also necessary to ensure the reliability of the results of such evaluation.

### SUMMARY OF THE INVENTION

One aspect of the present disclosure is an apparatus for automated measurements on drill cuttings comprising a catcher to collect a portion of the drill cuttings directly from a shaker, an at least one pneumatic actuator to move the collected portion of the drill cuttings from the catcher into a measurement sensitivity area created by a measurement module, the measurement module having a hermetically sealed enclosure. The sensitivity area is formed outside the enclosure and surrounded by the measurement module. The measurement module and the pneumatic actuator are controlled by an external control and data processing unit placed away from the oil well. The apparatus may also comprise a guide to define a rate of the cuttings collecting in the catcher. The measurement module can be a nuclear magnetic resonance (NMR) measurement module or other measurement modules that perform bulk sensitive measurements.

Another aspect of the present disclosure is a method of evaluating the rock formations while drilling an oil well. The method comprises a step of transferring the drill cuttings from a shaker into a measurement area, the area is formed outside a hermetically sealed measurement module and surrounded by the measurement module. The method comprises a step of running an at least one type of bulk sensitive measurements (e.g., NMR). A rate of transferring of the drill cuttings from the shaker into the measurement area is matched with a throughput of the measurement and the throughput of the measurement is matched with a desired spatial sampling rate of formations in the oil well being drilled. The method may include a periodic calibration of the measurements using a built-in calibration sample. The method further comprises processing and interpreting the measurement results to determine an at least one petrophysical parameter, and repeating the steps automatically to enable a substantially manless operation.

This summary is provided to introduce a selection of concepts that are further described below in the detailed description. This summary is not intended to identify key or essential features of the claimed subject matter, nor is it intended to be used as an aid in limiting the scope of the claimed subject matter. Other aspects and advantages of the invention will be apparent from the following description.

### BRIEF DESCRIPTION OF THE DRAWINGS

FIG. 1 illustrates an isometric view of a portion of the apparatus according to embodiments disclosed.

FIG. 2A, FIG. 2B, and FIG. 2C are partial cross-sectional views of apparatus in different steps of the apparatus operation.

FIG. 3A and FIG. 3B represent respectively a partial cross-sectional view of a NMR measurement module and NMR antenna/electronics interface.

FIG. 4 represents a partial cross-sectional view of a natural gamma spectroscopy (NGS) measurement module.

FIG. 5 illustrates a method of formation evaluation using automated measurements on drill cuttings.

### DETAILED DESCRIPTION OF THE INVENTION

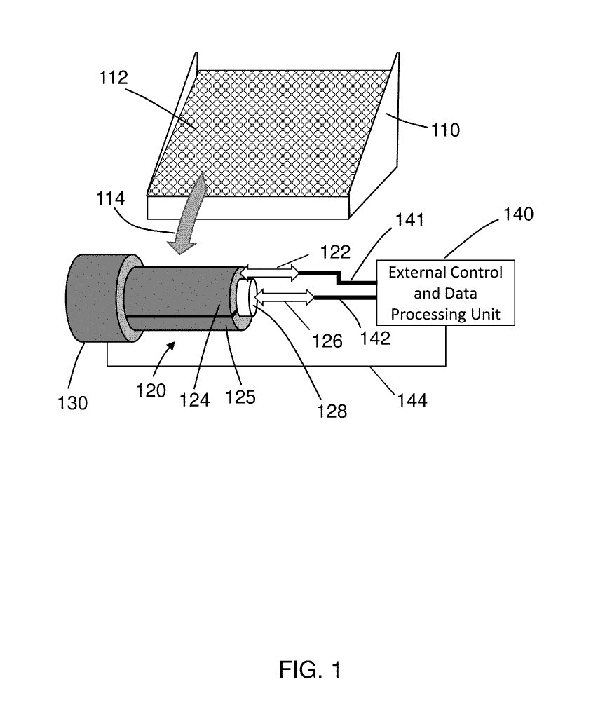

FIG. 1 illustrates an isometric view of a portion of the apparatus according to an embodiment disclosed. The drilling mud is passed through vibrating sieves 112 mounted on a shaker 110 where the rock cuttings (also called drill cuttings) are separated from the drilling mud (using the vibrating sieves). The separated cuttings fall over the edge of the sieves (the drill cuttings path is shown at 114) into is a sample catcher module 120 collecting the drill cuttings. The apparatus includes a measurement module 130 that forms a measurement sensitivity area (not shown in FIG. 1) to performs a bulk sensitive measurement (e.g. an NMR relaxation measurement) on the collected portion of the drill cuttings. The sample catcher module has a first pneumatic actuator 122 to control a cover 124 and a second pneumatic actuator 126 to move the cuttings collected in a catcher 125 (shown in FIG. 1 as a lower half pipe) into a measurement sensitivity area (not shown in FIG. 1). A sample piston 128 is used to move the collected portion of the cuttings. The measurement module is preferably placed in a hermetically sealed enclosure and filled with pressured nitrogen to avoid or mitigate accidental penetration of flammable vapors (that may be present near the shaker) inside the measurement module. In case the measurement module 130 is designed to perform NMR measurements the enclosure is preferably made of a non-conductive and non-magnetic material. The sensitivity area is located outside the sealed measurements module and surrounded by the measurement module. The catcher module and the measurement module may be mechanically decoupled from vibration produced by the shaker, e.g. suspended on a base decoupled from the shaker or/and using a vibration absorbing material (the suspension and the decoupling elements are not shown in FIG. 1). The measurement module 130 preferably comprises a sensor assembly and a front-end electronics. The sample catcher module 120 is connected to an external control and data processing unit 140 placed beyond a 100 feet zone around the oil well. The pneumatic actuators 122 and 126 are connected to the unit 140 using pressure lines 141 and 142. The measurement module 130 is connected to the external unit 140 using electrical or optical lines 144 (power supply, telemetry, etc.) and a hermetic feedthrough connector (not shown in FIG. 1). The external unit may comprise control electronics, pressure reservoir, relays, valves (acting valves relieve valves), a computer to control the processes associated with the measurements as well as to process and interpret the measurements results (including related software).

A position of the apparatus relative to the edge of the shaker (the edge of the sieves) can be selected to adjust the rate of collecting the drill cuttings in the catcher. Alternatively, a guide (not shown in FIG. 1) controlling the total amount of cuttings flowing into the sample catcher module can be used.

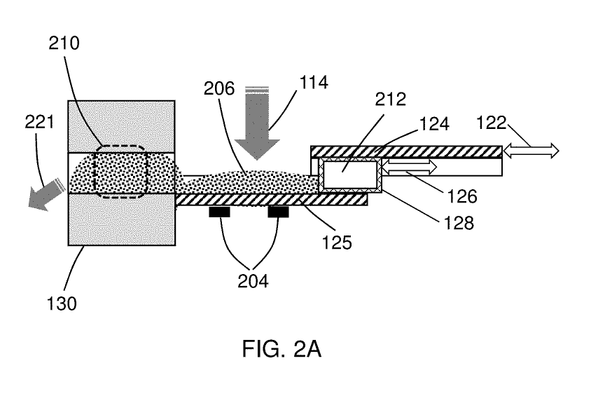

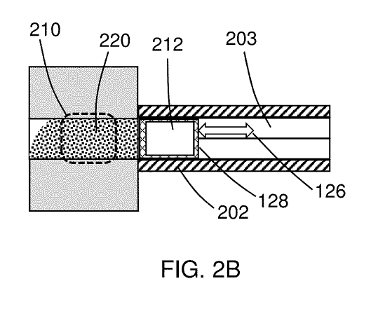

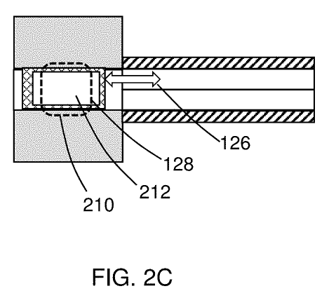

The apparatus may also include a weight sensor (not shown in FIG. 1, shown in FIG. 2A at 220) to be used for activation of the pneumatic actuators when the portion of the collected cuttings reaches a certain target weight. The apparatus may also include an optical device to be used for activation of the pneumatic actuators when the portion of the collected cuttings fills the catcher up to a certain target level. In another embodiment of the present disclosure the pneumatic actuator may be activated when a time of collecting the portion of the cuttings has reached a predetermined limit.

FIG. 2A, FIG. 2B, and FIG. 2C are partial cross-sectional views of the apparatus in different steps of the apparatus operation. FIG. 2A shows a partial sectional view of the apparatus when collecting the cuttings from the shaker. The cuttings from the shaker (the trajectory of the cuttings is shown at 114) are collected in a half pipe catcher 125. The collecting of the current portion of the cuttings is considered complete when readings of weight sensors 204 reach a preset threshold. Alternatively, an optical device (e.g., including an optical source and an optical detector, not shown in FIG. 2A) can be used to assess the amount of the drill cuttings collected in the catcher 125. The first pneumatic actuator 122 is activated to place the cover 124 over the half pipe catcher 125 making a channel (203 in FIG. 2B) to guide the newly collected portion of cuttings 206 into a measurement area surrounded by the measurement module 130. Then the second pneumatic actuator 126 is activated to advance the newly collected portion of cuttings 206 into the measurement sensitivity area, the boundary of which is shown at 210 as a dashed line. The sensitivity area is surrounded by the hermetically sealed measurement module 130. Advancing of the newly collected portion of cuttings is performed using the piston 128. The previous portion of the cuttings displaced from the measurement sensitivity area while advancing the new portion of cuttings is directed (the direction is represented by the arrow 221) into the cuttings dumping channel (not shown). A fraction of the cuttings may be also loaded in a container for further measurements at a mud logging station or in a laboratory. The piston 128 may have a built-in calibration sample 212.

In some embodiments the catcher 125 may have a rectangular cross-section and the cover 124 may be a flat cover. In some embodiments the catcher module 120 and the measurement module 130 may be positioned vertically or at an angle to the vertical direction to let gravity assist transferring cuttings from the catcher to the measurement area and further to the cutting dumping channel. A pneumatic actuator may be used as a stopper to control flow of the cuttings. Alternatively, the drill cuttings may flow continuously (vertically without stopping) and the measurement may be done while the cuttings move through the sensitivity area. In this case the cutting flow rate through the sensitivity area may be controlled (e.g., by adjusting a measurement module axis direction with respect to the vertical direction) to allow a desired time for the cuttings presence in the measurement sensitivity area 210.

FIG. 2B shows the partial cross-sectional view with the collected drill cuttings displaced (by the actuator 126 and the piston 128 guided via the channel 203) to a new position 220 where the measurement is conducted. The drill cuttings in the new position preferably fills the length of the sensitivity area 210 and the diameter of the channel 203 is preferably smaller than the diameter of the sensitivity area. When the collected portion of the cuttings arrives to the measurement module area at the position 220 the measurement cycle starts and the piston 128 is immediately moved back to the position shown in FIG. 2A by the actuator 126. Then the cover 124 is moved back to the position shown in FIG. 2A by the actuator 122 to open access for the cuttings coming from the shaker into a half pipe catcher 125 so the next portion of the cuttings can be collected.

To ensure a substantially continuous sampling of the drill cuttings coming from the shaker the time to collect a new portion of the drill cuttings is set to be substantially equal to the time needed to complete measurement on one portion of the cuttings (the measurement cycle). This may be achieved by controlling the rate of collecting the cuttings in the catcher 125. As explained above, the rate may be controlled either by a proper positioning of the apparatus relative to the edge of the sieves or by using a guide controlling the total amount of cuttings flowing into the catcher 125 from the shaker. The measurement module 130 is preferably designed to enable the measurement cycle matching a target spatial resolution for formation evaluation. For example, if the target resolution is 5 feet, then, for a 100 feet/hour drilling rate of penetration, the requirement for the measurement cycle duration is 3 min.

Continuous automated measurements may require a periodic calibration (the need for calibration may be related, for example, to changing the temperature of the environment during measurements). The calibration may be done using the calibration sample 212 (FIG. 2A, FIG. 2B) placed inside the piston 128 (FIG. 1, FIG. 2A, FIG. 2B). The calibration sample preferably contains a known amount of substance, to which the measurement is sensitive. In case of NMR measurement, the calibration sample may contain a fluid with known amount of hydrogen per unit volume, for example, the calibration fluid can be water (preferably doped with copper sulfate) or a liquid hydrocarbon. FIG. 2C is a partial cross-sectional view of the apparatus of the present disclosure showing the position of the piston 128 (with the calibration sample 212) inside the sensitivity area 210. The piston is moved into this position by the actuator 126 during calibration mode. The geometry of the calibration sample 212 is selected to substantially fill the sensitivity area.

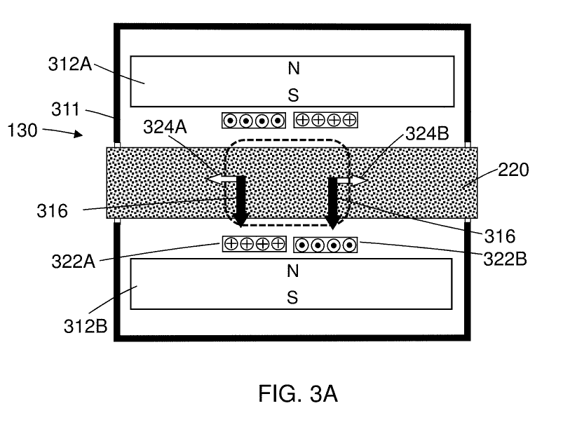

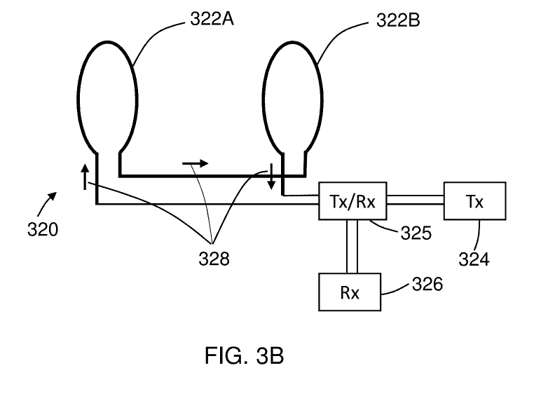

FIG. 3A and FIG. 3B represent respectively a partial cross-sectional view of NMR measurement module and NMR antenna/electronics interface. The NMR module presented in FIG. 3A includes a magnet assembly comprising magnets 312A and 312B to generate a static magnetic field 316 in the sensitivity area and an antenna comprising two sections 322A and 322B to generate a radio-frequency (RF) magnetic field presented at 324A and 324B. The static magnetic field and the RF magnetic field are mutually orthogonal. Well-site operation may be accompanied by a strong electromagnetic noise affecting NMR measurements. The antenna sections 322A and 322B are properly connected to make a differential antenna. This (differential) configuration serves the purpose of substantially eliminating the environmental noise voltage in the RF antenna as explained further below. Also, an electromagnetic shield 311 may be used to further reduce the noise. The shield 311 may be placed outside or inside the hermetic enclosure of the measurement module (also, an external part of the hermetic enclosure may serve as the electromagnetic shield). In case the shielding effect of the electromagnetic shield is sufficient to eliminate the environmental noise, a single section antenna configuration may be used (e.g., just the antenna section 322A).

FIG. 3B represents an antenna and an antenna/electronics interface of the NMR module. It shows another view of the differential antenna (shown at 320 in FIG. 3B). Direction of the antenna current is shown at 328. The RF antenna is a transceiver antenna that is used in the transmit mode for generating the RF magnetic field (in the transmit mode the antenna is driven from the transmitter electronics 324) and in the receive mode (in the receive mode the antenna is connected to the receiver 326). Switching between the modes is performed by the switching circuitry 325.

The effect of the differential antenna to essentially eliminate the residual external noise in the RF antenna is explained below. The total signal in each section (subscripts 1 and 2 correspond to the first and second section respectively) of the differential antenna can be presented as

E_{1,2}=E_{NMR1,2}+E_{TN1,2}+E_{EN1,2} (1)

Here E_{NMR1,2} is the NMR signals in the first and second sections of the differential antenna respectively, E_{TN1,2} is the thermal noise in the first and second section respectively, and E_{EN1,2} is the external (environmental) electromagnetic noise in the first and second section respectively.

The signals E_{NMR1,2} can be presented:

E_{NMR1,2}=ω·∫_{SV}\vec{M}_{1,2}·\vec{S}_{1,2}·dv, (2)

where \vec{M}_{1,2} is the nuclear magnetization; \vec{S}_{1,2} is the antenna sensitivity that, according to the reciprocity theorem, can be expressed as

$${\vec{S}}_{1 , 2} = \frac{{\vec{B}}_{RF 1 , 2}}{I} \qquad ( 3 )$$

with \vec{B}_{RF1,2} denoting the RF magnetic field generated by an antenna section driven by the current I.

The RF magnetic field and the sensitivity of the first and the second section of the differential antenna are in opposite directions (324A, 324B in FIG. 3A), therefore for the identical sections we have:

\vec{S}₁=−\vec{S}₂ (4)

and

\vec{M}₁=−\vec{M}₂. (5)

Thus, for the NMR signals we have

E_{NMR1}=E_{NMR2}. (6)

Due to the equation (4) the external noise from a remote source in the antenna sections are strongly correlated and has opposite phases while the thermal noise may be considered substantially uncorrelated. Therefore, the total signal in the differential antenna substantially does not contain the external noise:

E_{Σ}=2E_{NMR}+\sqrt{2}E_{TN}, (7)

where E_{NMR} and E_{TN} are the NMR signal and the thermal noise in one antenna section.

NMR measurements on drill cuttings may aim NMR properties of residual fluids in the porous space of the cuttings fragments including transversal and longitudinal relaxation times and the amount of fluids in the porous space. The amount of fluids is determined by comparison of the NMR signal obtained from the cuttings filling the sensitivity area 210 and the signal from the calibration sample. To interpret the NMR data, the amount of fluids is preferably normalized to a volume or mass of the cuttings fragments. The mass of the cuttings in the sensitive area can be calculated using an estimate of packing density of the drill cuttings fragments in the measurement area. The estimate may be obtained by weighing the total amount of cuttings 220 in the area surrounded by the measurement module using a weight sensor (not shown in FIG. 2A, FIG. 2B, FIG. 2C). The mass m_{SA} of the drill cuttings in the sensitivity area 210 can be then calculated as

$${m}_{SA} = {m}_{T} \cdot \frac{{v}_{SA}}{{v}_{T}} , \qquad ( 8 )$$

where m_{T} is the mass of the cuttings in the area surrounded by the measurement module, v_{T} is the volume (known) of the area surrounded by the measurement module, and v_{SA} is the volume of the sensitivity area 210.

The NMR measurements on drill cuttings may be used, for example, to assess the amount of clay fluids and fluids inside organic and inorganic nano-pores. Residual fluids on the external surface of the cuttings fragments may be separated from the intra-pore fluids using NMR relaxation spectra (the transversal relaxation times of the fluids on the external surface of the cuttings fragments are typically longer that of the intra-pore fluids). The NMR signals from the residual fluid on the surface of the cuttings fragments may mask the NMR signals from the intra-pore fluids (the prime target of the NMR measurement). A hot air may be used during collecting the cuttings to substantially remove the residual fluid on the surface of the cuttings fragments. The air may be transferred from the external unit (140, FIG. 1) to the catcher module (120, FIG. 1) via an air hose.

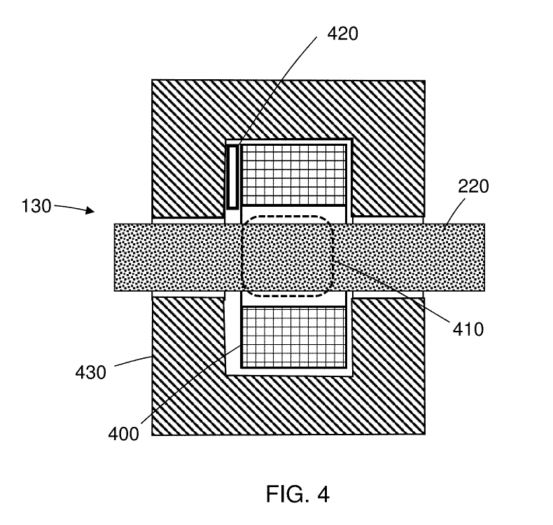

FIG. 4 represents a partial cross-sectional view of an embodiment of the measurement module 130 designed to perform natural gamma spectroscopic (NGS) measurements. The NGS measurement module comprises a NaI crystal 400 or multiple crystals to detect natural gamma rays. The crystal (crystals) preferably surrounds the sensitivity area 410. The measurement module may include a photomultiplier 420 and a lead shield 430. The crystal, the photomultiplier and some other front-end electronics are preferably placed inside the hermetic enclosure of the measurement module. The lead shield 430 may be positioned inside or outside the hermetic enclosure of the measurement module. In case of the NGS measurements the calibration sample 212 (FIG. 2A, FIG. 2B, FIG. 2C) may contain KCl to automatically assign a specific energy channel to the Potassium signal. The NGS data is typically normalized to the mass of the cuttings in the NGS sensitivity area. The mass is measured using a weight sensor placed in the measurement area (not shown in FIG. 4). The NGS measurements and processing are typically performed to determine concentrations of Potassium, Uranium and Thorium in the rock formations.

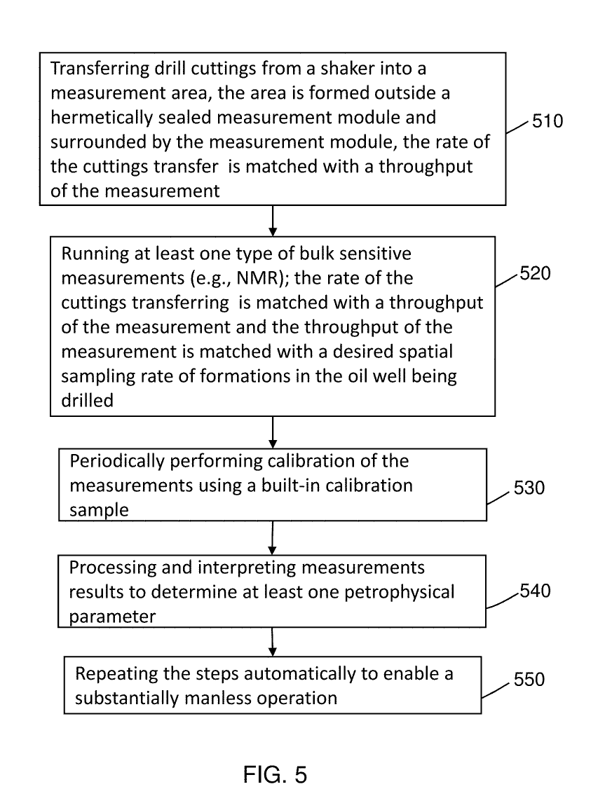

FIG. 5 illustrates a method of formation evaluation using automated measurements on drill cuttings. The method includes a step 510 of transferring drill cuttings from the shaker into the measurement area formed outside the hermetically sealed measurement module and surrounded by the measurement module. The step of transferring cuttings may comprise the steps of collecting the cuttings from the shaker in the catcher using the piston controlled by the pneumatic actuator and then transferring the cuttings into the measurement area including the sensitivity area. The pneumatic actuator may be activated when one of the following occurs: (i) the collected portion of cuttings reaches a predetermined weight threshold, (ii) the time of collecting of the portion of cuttings in the catcher reaches a predetermined time threshold, or (iii) the cuttings collected in the catcher reaches a certain level detected by an optical means. The method includes a step 520 of running at least one type of bulk sensitive measurements (e.g., NMR, NGS or electrical resistivity). The rate of the cuttings transfer is preferably matched with a throughput of the measurement. The throughput of the measurement is preferably matched with a desired spatial sampling rate of the rock formations properties in the oil well being drilled. The method may also include a step 530 of periodically calibrating the measurements using a calibration sample built into the piston (128, FIG. 1). The method further includes a step 540 of processing measurement data and interpreting measurements results to determine at least one petrophysical parameter of the rock formations being drilled (e.g. an amount and type of a residual fluid in the pore space in case of NMR measurements and concentration of Uranium, Thorium and Potassium in a rock in case of NGS measurements). The step 540 may include determining the mass of the cuttings in the sensitivity area and using the mass to normalize the measurement data. The method includes repeating the steps above to enable a substantially manless operation (step 550 in FIG. 5).

While the invention has been described with respect to a limited number of embodiments, those skilled in the art, having benefits of this disclosure, will appreciate that other embodiments can be devised (particular illustrative embodiments disclosed above may be altered combined, or modified), which do not depart from the scope of invention as disclosed herein. The apparatus and methods illustratively disclosed herein may be practiced in the absence of any element that is not specifically disclosed herein and/or any optional element disclosed herein.

What I claim as my invention is:

1. An apparatus to perform automated measurements on drill cuttings, comprising:
a sample catcher to collect a portion of the drill cuttings directly from a shaker;
a measurement module creating a measurement sensitivity area; and
an at least one actuator to move the collected portion of the drill cuttings from the sample catcher into the measurement sensitivity area.

2. The apparatus of claim 1, wherein the at least one actuator is a pneumatic actuator.

3. The apparatus of claim 2 further comprising an external control and data processing unit placed away from the shaker to control the measurement module and the pneumatic actuator.

4. The apparatus of claim 1, wherein the measurement module performs at least one of (i) nuclear magnetic resonance measurements and (ii) natural gamma spectroscopy measurements.

5. The apparatus of claim 1, wherein the measurement module has a hermetically sealed enclosure and the measurement sensitivity area is formed outside the enclosure.

6. The apparatus of claim 1 further comprising at least one of (i) a weight sensor to activate the at least one actuator when the collected portion of the drill cuttings reaches a target weight, (ii) an optical device to activate the at least one actuator when the collected portion of the drill cuttings fills the sample catcher up to a target level and (iii) a timer to activate the at least one actuator when a time of collecting the portion of the drill cuttings has reached a predetermined limit.

7. The apparatus of claim 1 further comprising a piston operatively connected to the at least one actuator and a calibration sample, the calibration sample built into the piston to perform automatic calibration of the apparatus.

8. An apparatus to perform nuclear magnetic resonance measurements in an area with environmental electromagnetic noise present, the apparatus comprising:
a magnet assembly to generate a static magnetic field in a measurement sensitivity area; and
an antenna to generate a radio-frequency magnetic field and receive nuclear magnetic resonance signals, the antenna comprising two sections connected to make a differential antenna, the differential antenna substantially eliminating the environmental electromagnetic noise voltage in the antenna;

9. The apparatus of claim 8, wherein the area with environmental electromagnetic noise present is a well site and the nuclear magnetic resonance measurements are performed to evaluate subsurface formations.

10. The apparatus of claim 8 further comprising an electromagnetic shield to further reduce the environmental electromagnetic noise voltage in the antenna.

11. A method of formation evaluation using automated measurements on drill cuttings, comprising:
collecting a portion of the drill cuttings in a sample catcher at a shaker;
transferring the portion of the drill cuttings from the sample catcher into a measurement area using an at least one actuator, the measurement area including a measurement sensitivity area;
performing at least one type of bulk sensitive measurements; and
processing the bulk sensitive measurement data to determine at least one petrophysical parameter of the rock formations being drilled.

12. The method of claim 11, wherein the step of transferring cuttings further comprises moving an at least a fraction of the portion of the drill cuttings after the measurement into a sample jar for further analysis.

13. The method of claim 11, wherein the measurement sensitivity area is formed outside a hermetically sealed measurement module and the at least one actuator is a pneumatic actuator.

14. The method of claim 11, wherein the at least one actuator is activated when one of the following occurs: (i) the collected portion of drill cuttings reaches a predetermined weight threshold, (ii) the time of collecting of the portion of drill cuttings in the sample catcher reaches a predetermined threshold, (iii) the collected portion of drill cuttings in the sample catcher reaches a predetermined level detected by an optical means.

15. The method of claim 11, wherein the at least one type of bulk sensitive measurements is nuclear magnetic resonance measurements.

16. The method of claim 11 further including matching a throughput of the measurements with a desired spatial sampling rate of the rock formations properties.

17. The method of claim 11, wherein the step of performing at least one type of bulk sensitive measurements further includes automatically calibrating the measurements using a calibration sample built into a piston operatively connected to the at least one actuator.

18. The method of claim 11, wherein the step of processing includes determining a mass of the portion of the drill cuttings in the measurement sensitivity area and using the mass to normalize the measurement data.
